(19) United States
(12) Patent Application Publication
(10) Pub. No.: US 2025/0254886 A1
(43) Pub. Date: Aug. 7, 2025

(54) FERROELECTRIC MEMORY DEVICES WITH A THREE-DIMENSIONAL TOPOGRAPHY STRUCTURE

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 18/430,511

(22) Filed: Feb. 1, 2024

(51) Int. Cl. H10B 53/30

(52) U.S. Cl. CPC H10B 53/30

(57) ABSTRACT

In accordance with some embodiments of the present disclosure, a memory device is provided. The memory device may include a three-dimensional (3D) feature fabricated on a connection pad that comprises a conductive material, a first electrode fabricated on the 3D feature, a ferroelectric layer fabricated on the first electrode, and a second electrode fabricated on the ferroelectric layer. The ferroelectric layer may include at least one ferroelectric material, such as hafnium oxide (HfO₂), zirconium oxide (ZrO₂), zirconium-doped hafnium oxide (Hf₁₋ₓZrₓO₂), scandium-doped aluminum nitride (Al₁₋ₓScₓN), titanates (BaTiO₃), niobates (LiNbO₃), tantalates (NaTaO₃), etc. The 3D feature is a post, a fin, a trench, a via, etc.

### TECHNICAL FIELD

The implementations of the disclosure generally relate to memory and computing devices and, more specifically, to ferroelectric memory devices with a three-dimensional (3D) topography structure.

### BACKGROUND

Ferroelectric materials may refer to materials that exhibit a spontaneous electric polarization that can be reversed in direction by the application of a suitable electric field, such as hafnium oxide (HfO₂), zirconium oxide (ZrO₂), zirconium-doped hafnium oxide (Hf₁₋ₓZrₓO₂), scandium-doped aluminum nitride (Al₁₋ₓScₓN), titanates (BaTiO₃), niobates (LiNbO₃), tantalates (NaTaO₃), etc. The ferroelectric materials may remain polarized even when the electric field is removed. As such, the ferroelectric materials may store data when power is disconnected from it. This makes the ferroelectric materials promising candidates for implementing non-volatile memory that remains stored data even when its external power supply is disconnected.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a memory device is provided. The memory device includes: a three-dimensional (3D) feature fabricated on a connection pad that includes a conductive material; a first electrode; a ferroelectric layer fabricated on the first electrode; and a second electrode fabricated on the ferroelectric layer. At least a portion of the first electrode is fabricated on a surface of the 3D feature. The ferroelectric layer includes a ferroelectric material

In some embodiments, the 3D feature includes at least one of a post, a fin, a trench, or a via.

In some embodiments, the 3D feature includes an opening fabricated in a dielectric layer, wherein the dielectric layer is fabricated on the connection pad.

In some embodiments, the 3D feature exposes at least a portion of the connection pad, and wherein at least a portion of the first electrode is fabricated on the exposed portion of the connection pad.

In some embodiments, at least a portion of the first electrode is fabricated on a top surface of the dielectric layer and on sidewalls of the 3D feature.

In some embodiments, the connection pad is fabricated on a substrate, and wherein the 3D feature extends out of a two-dimensional plane of a top surface of the substrate.

In some embodiments, at least a portion of the first electrode is fabricated on a top surface of the 3D feature and a top surface of the connection pad.

In some embodiments, the ferroelectric material includes a metal oxide, and wherein the metal oxide includes at least one of hafnium oxide (HfO₂), zirconium oxide (ZrO₂), zirconium-doped hafnium oxide (Hf₁₋ₓZrₓO₂ with x ranging from 0 to 1), scandium-doped aluminum nitride (Al₁₋ₓScₓN with x>0.3), titanates (BaTiO₃), niobates (LiNbO₃), or tantalates (NaTaO₃).

In some embodiments, the ferroelectric material is interstitially doped with at least one interstitial dopant, and wherein the at least one interstitial dopant includes at least one of H, N, C, B, or F.

In some embodiments, the first electrode includes at least one of tungsten, ruthenium, molybdenum, titanium nitride, tantalum nitride, tungsten nitride, platinum, palladium, or iridium.

In some embodiments, the second electrode includes at least one of tungsten, ruthenium, molybdenum, titanium nitride, tantalum nitride, tungsten nitride, platinum, palladium, or iridium.

According to one or more aspects of the present disclosure, methods for fabricating a memory device are provided. The methods include: fabricating, on a connection pad including a conductive material, a three-dimensional (3D) feature, wherein the connection pad is fabricated on a substrate; fabricating a first electrode layer on the substrate, the connection pad, and the 3D feature; fabricating, on the first electrode layer, a ferroelectric layer including a ferroelectric material; and fabricating, on the ferroelectric layer, a second electrode layer.

In some embodiments, the 3D feature includes at least one of a post, a fin, a trench, or a via.

In some embodiments, fabricating, on the connection pad, the 3D feature includes fabricating a dielectric layer with an opening on the connection pad.

In some embodiments, the 3D feature exposes at least a portion of the connection pad, and wherein at least a portion of the first electrode is fabricated on the exposed portion of the connection pad.

In some embodiments, at least a portion of the first electrode is fabricated on a top surface of the dielectric layer and sidewall of the opening of the dielectric layer.

In some embodiments, the connection pad is fabricated on a substrate, and wherein the 3D feature extends out of a two-dimensional plane of a top surface of the substrate.

In some embodiments, at least a portion of the first electrode is fabricated on a top surface of the 3D feature and a top surface of the connection pad.

In some embodiments, the ferroelectric material includes a metal oxide, and wherein the metal oxide includes at least one of hafnium oxide (HfO₂), zirconium oxide (ZrO₂), zirconium-doped hafnium oxide (Hf₁₋ₓZrₓO₂ with x ranging from 0 to 1), scandium-doped aluminum nitride (Al₁₋ₓScₓN with x>0.3), titanates (BaTiO₃), niobates (LiNbO₃), or tantalates (NaTaO₃).

In some embodiments, the first electrode includes at least one of tungsten, ruthenium, molybdenum, titanium nitride, tantalum nitride, tungsten nitride, platinum, palladium, or iridium, and wherein the second electrode includes at least one of tungsten, ruthenium, molybdenum, titanium nitride, tantalum nitride, tungsten nitride, platinum, palladium, or iridium.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIGS. 1A and 1B illustrate cross-sectional views of example memory devices in accordance with some embodiments of the present disclosure.

FIGS. 2A, 2B, 2C, 2D, 2E, and 2F illustrate structures related to a process for fabricating a memory device in accordance with some embodiments of the present disclosure.

FIGS. 3A, 3B, 3C, 3D, 3E, and 3F illustrate structures related to a process for fabricating a memory device in accordance with some embodiments of the present disclosure.

FIG. 4 is a flow chart illustrating an example process for fabricating a memory device in accordance with some embodiments of the present disclosure.

FIG. 5A is a flow chart illustrating an example process for fabricating an interconnect structure including a metallic via and a metallic pad in one process.

FIGS. 5B-5G illustrate cross-sectional views of structures for fabricating an interconnect structure in accordance with some embodiments of the present disclosure.

### DETAILED DESCRIPTION

Aspects of the present disclosure provide ferroelectric memory devices and methods for making the same. The ferroelectric memory devices may be part of ferroelectric random-access memories (Fe-RAM), such as a capacitor (e.g., ferroelectric capacitor (FeCAP)), a transistor (e.g., ferroelectric field-effect transistor (FeFET)), a ferroelectric tunneling junction (FTJ), a ferroelectric random-access memory (FeRAM), etc.

A ferroelectric material may be polarized in response to the application of an external electric field and may remain polarized even when the external electric field is removed. The reversible spontaneous polarization arises from non-centrosymmetric arrangements of ions in the ferroelectric material that produces a permanent electric dipole moment. Adjacent dipoles tend to orient themselves in the same direction to form a region referred to as a ferroelectric domain.

A material may have multiple polymorphs of varying ferroelectric properties. For example, HfO₂ may exhibit a monoclinic phase (m-phase) between room temperature and 1670° C. As the temperature increases, HfO₂ may undergo a phase transition from monoclinic (m-phase) to tetragonal (t-phase) and then to cubic (c-phase). HfO₂ does not exhibit ferroelectricity in the m-phase, the t-phase, or the c-phase. HfO₂ may exhibit ferroelectricity in a polar orthorhombic phase (o-phase). Although the m-HfO₂ phase is the most stable phase around ambient temperature thermodynamically, the o-HfO₂ phase shows distinctive properties due to its intrinsic non-centrosymmetric polar and ferroelectric behavior. Ferroelectricity in materials relates to the permanent electrical polarization of a crystalline dielectric under an electric field. Ferroelectric materials exhibit bi-state polarization behaviors, enabling them to store binary information of “0” and “1” in a non-volatile manner, making them suitable for memory devices.

A FeRAM device typically includes a planar MIM (Metal-Insulator-Metal) capacitor structure, where ‘M’ represents metal and ‘I’ typically represents an insulator. In FeRAM, the T′ is replaced by ferroelectric materials. Scaling down such a FeRAM device may reduce its size but may result in a decreased amount of ferroelectric material in the FeRAM device and may consequently reduce the ferroelectric signal measurable from the device. Therefore, optimizing the MIM size while maintaining a smaller silicon footprint is desirable for enhancing FeRAM performance at a lower cost.

The present disclosure provides ferroelectric memory devices and methods for fabricating the same. A memory device may include a ferroelectric device stack fabricated on a three-dimensional (3D) feature. The 3D feature may either extend out of the two-dimensional plane of the top surface of a substrate on which the ferroelectric device stack is fabricated or is etched into and/or fabricated within the substrate. For example, the ferroelectric device stack may be fabricated over a post, a fin, etc. As another example, the ferroelectric device stack may be fabricated within a via, a trench, etc. The ferroelectric device stack may be regarded as a 3D FeRAM device as it is fabricated on a 3D feature. Compared to a planar ferroelectric device stack with planar ferroelectric films, the 3D ferroelectric device described herein may have increased total surface area, allowing for more ferroelectric material in the device without increasing its overall footprint. This ultimately enhances the ferroelectric signal without sacrificing size or cost efficiency.

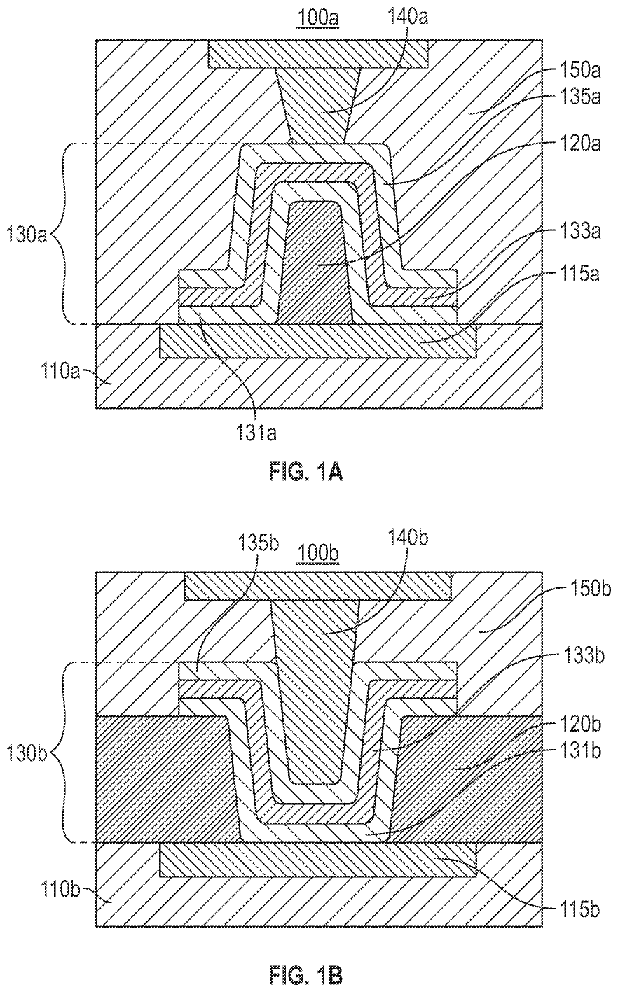

FIGS. 1A and 1B illustrate cross-sectional views of example memory devices 100a and 100b in accordance with some embodiments of the present disclosure.

As shown in FIG. 1A, memory device 100a may include a substrate 110a, a 3D feature 120a, a first connection pad 115a, a ferroelectric device stack 130a, and a second connection pad 140a. Second connection pad 140a may include a connection via (e.g., a metallic via) and a connection pad (e.g., a metallic pad) in some embodiments. Memory device 100a may further include a dielectric layer 150a surrounding second connection pad 140a and ferroelectric device stack 130a. The memory device 100a may be a non-volatile memory device that can retain stored data even when it is not powered.

Substrate 110a may include any suitable materials for providing a base for the fabrication of the memory device, such as silicon, sapphire, silicon carbide, etc. In some embodiments, substrate 110a may include a driving circuit including one or more electrical circuits (e.g., an array of electrical circuits) that may be individually controllable. In some embodiments, the driving circuit may include one or more complementary metal-oxide-semiconductor (CMOS) drivers.

First connection pad 115a may be fabricated on substrate 110a. In one implementation, the top surface of first connection pad 115a is elevated above the top surface of substrate 110a. First connection pad 115a may include any suitable conductive material for providing ohmic contact for the device fabricated on first connection pad 115a, such as metals, metal nitrides, alloys, etc. In some embodiments, substrate 110a may be a CMOS substrate, and first connection pad 115a may include an interconnect of the CMOS substrate (e.g., a metallic pad, metallic via, etc.).

3D feature 120a may be a post, a fin (i.e., a thin wall), or any other suitable structure that is fabricated on first connection pad 115a and extend out of the two-dimensional plane of the top surface of substrate 110a. 3D feature 120a may cover a portion of the top surface of first connection pad 115a but not the entire top surface of first connection pad 115a. 3D feature 120a may include one or more dielectric materials, such as silicon dioxide (SiO₂), silicon nitride (Si₃N₄), etc.

Ferroelectric device stack 130a may be conformally fabricated on and along the top surface of substrate 110a, first connection pad 115a, and the sidewalls of 3D feature 120a.

Ferroelectric device stack 130a may include a first electrode 131a, a ferroelectric layer 133a, and a second electrode 135a. First electrode 131a may include any suitable electrically conductive material. As an example, first electrode 131a may include metals such as tungsten (W), ruthenium (Ru), molybdenum (Mo), platinum (Pt), palladium (Pd), iridium (Ir), etc. As another example, first electrode 131a may include nitrides, such as titanium nitride (TiN), tantalum nitride (TaN), tungsten nitride (WN), etc. As illustrated in FIG. 1A, first electrode 131a may be conformally fabricated on the top surface of substrate 110a, first connection pad 115a, and 3D feature 120a, and along the sidewalls of 3D feature 120a. In some embodiments, one or more portions of first electrode 131a may directly contact the top surface of first connection pad 115a.

Ferroelectric layer 133a may include one or more ferroelectric films conformally fabricated on first electrode 131a. Each of the ferroelectric films may include a ferroelectric material. The ferroelectric material may include a metal oxide, such as hafnium oxide (HfO₂), zirconium oxide (ZrO₂), zirconium-doped hafnium oxide (Hf₁₋ₓZrₓO₂) with x ranging from 0 to 1, scandium-doped aluminum nitride (Al₁₋ₓScₓN) with x>0.3, titanates (BaTiO₃), niobates (LiNbO₃), tantalates (NaTaO₃), etc. In some embodiments, the metal oxide may be doped with one or more substitutional and/or interstitial dopants that may occupy the vacant space between the atoms of the ferroelectric material. The interstitial dopant may include an element having an atomic radius that is not greater than an atomic radius of a metal element of the metal oxide. The metal oxide may include at least one of hafnium or zirconium. The interstitial dopant may include a nonmetal element, such as H, N, C, B, F, etc. The interstitial dopants may be introduced in the ferroelectric film utilizing an ion implantation method, a co-sputtering method, an alternating sputtering method, a thermal diffusion method, a chemical absorption method, and/or any other suitable technique. In some embodiments, the dopant concentration of the interstitial dopants(s) may be about or less than 10%. As illustrated in FIG. 1A, ferroelectric layer 133a may be conformally fabricated on first electrode 131a, and thus fabricated on the top surface of first connection pad 115a, the top surface of 3D feature 120a, and along the sidewalls of 3D feature 120a.

Second electrode 135a may include any suitable electrically conductive material conformally fabricated on ferroelectric layer 133a. For example, second electrode 135a may include metals, such as W, Ru, Mo, Pt, Pd, Ir, etc., and/or nitrides (e.g., TiN, TaN, WN, etc.). Second electrode 135a and first electrode 131a may or may not include the same materials. As illustrated in FIG. 1A, second electrode 135a may be conformally fabricated on ferroelectric layer 133a, and thus fabricated on the top surface of first connection pad 115a, the top surface of 3D feature 120a, and along the sidewalls of 3D feature 120a.

Second connection pad 140a may contain any suitable conductive material for providing ohmic contact for ferroelectric device stack 130a, such as metals, metal nitrides, alloys, etc. In some embodiments, second connection pad 140a may include one or more interconnects (e.g., a metallic pad, metallic via, etc.). As shown, second connection pad 140a may be fabricated in dielectric layer 150a. Dielectric layer 150a may include one or more suitable dielectric materials and be fabricated on first connection pad 115a. Dielectric layer 150a may cover ferroelectric device stack 130a.

Referring to FIG. 1B, memory device 100b may include a substrate 110b, a dielectric layer 120b, a first connection pad 115b, a ferroelectric device stack 130b, and a second connection pad 140b. In some embodiments, second connection pad 140b may include a connection via and a connection pad. The memory device 100b may be a non-volatile memory device that can retain stored data even when it is not powered. Substrate 110b may be the same as substrate 110a. First connection pad 115b may be the same as first connection pad 115a.

Dielectric layer 120b may include one or more layers of one or more dielectric materials (e.g., SiO₂, Si₃N₄, etc.) with a 3D feature (e.g., a via, a trench, etc.) that is etched into and/or fabricated within substrate 110b and exposes at least a portion of the top surface of first connection pad 115b. Thus, dielectric layer 120b does not cover at least a portion of first connection pad 115b. Ferroelectric device stack 130b may be fabricated within the 3D feature and on the top surface of dielectric layer 120b

Ferroelectric device stack 130b may include first electrode 131b, ferroelectric layer 133b, and second electrode 135b. First electrode 131b and first electrode 131a may contain the same material. As shown in FIG. 1B, first electrode 131b may be conformally fabricated in the 3D feature in dielectric layer 120b and on the top surface of dielectric layer 120b. In particular, part of first electrode 131b is fabricated on the exposed portion of first connection pad 115b (i.e., the portion not covered by dielectric layer 120b and exposed by the 3D feature), extending over the top of the 3D feature and along its sidewalls.

Ferroelectric layer 133b may be fabricated on first electrode 131b. As such, a portion of ferroelectric layer 133b is fabricated in the 3D feature. One or more portions of ferroelectric layer 133b may be fabricated on the top surface of dielectric layer 120b. Ferroelectric layer 133b and ferroelectric layer 133a may contain the same or substantially the same material.

Second electrode 135b may be fabricated on ferroelectric layer 133b. One or more portions of second electrode 135b may be fabricated in the 3D feature of dielectric layer 120b. One or more portions of second electrode 135b are fabricated on the top surface of dielectric layer 120b.

Second connection pad 140b may include any suitable conductive material to provide ohmic contact for ferroelectric device stack 130b. In some embodiments, a portion of second connection pad 140b is fabricated in the 3D feature of dielectric layer 120b. A dielectric layer 150b may surround one or more portions of second connection pad 140b and ferroelectric device stack 130b. The dielectric layer 150b may include one or more layers of one or more dielectric materials (e.g., SiO₂, Si₃N₄).

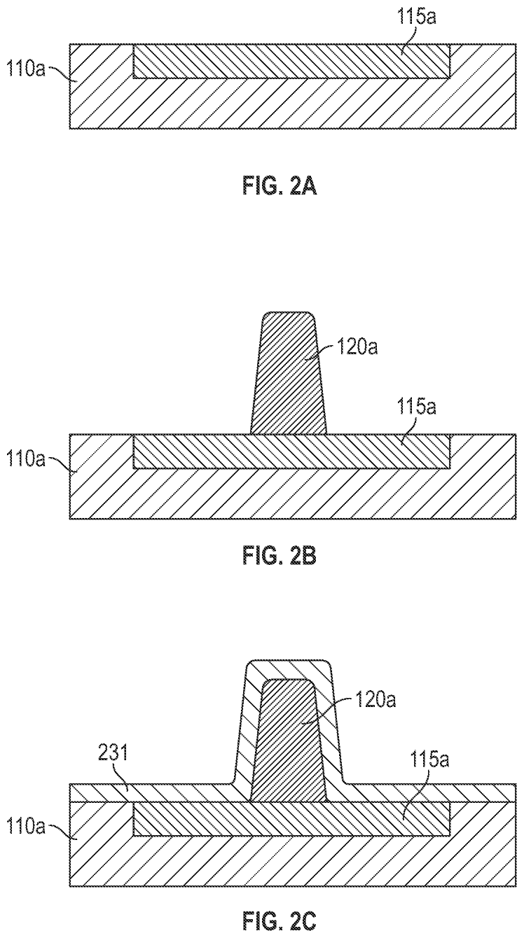

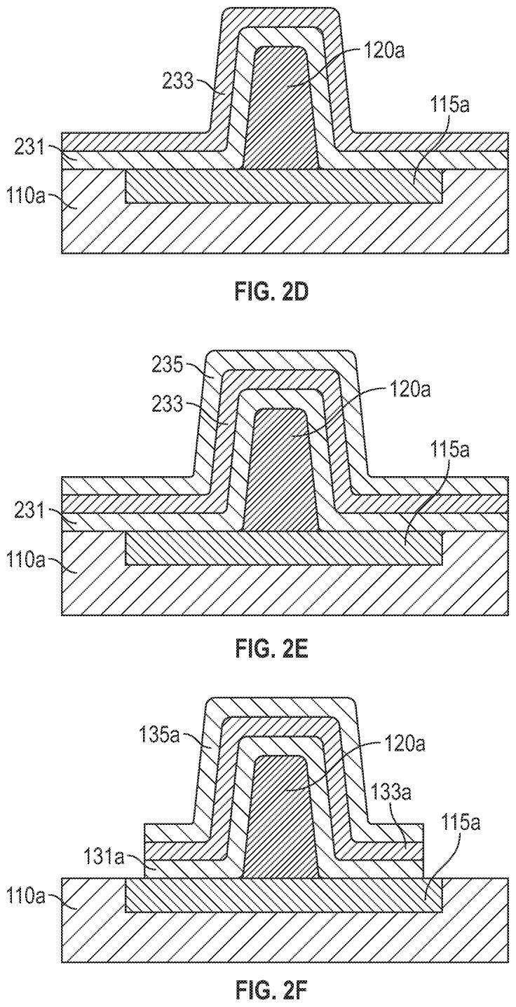

FIGS. 2A, 2B, 2C, 2D, 2E, and 2F illustrate structures related to a process for fabricating a memory device in accordance with some embodiments of the present disclosure.

As shown in FIG. 2A, a substrate 110a with a first connection pad 115a may be provided. First connection pad 115a may include any suitable conductive material, such as metals (e.g., tungsten (W)). In some embodiments, first connection pad 115a may be an interconnect of a CMOS substrate (e.g., a metallic pad, a metallic via, etc.).

As shown in FIG. 2B, 3D feature 120a may be fabricated on first connection pad 115a and substrate 110a. 3D feature 120a may be a post, a fin (i.e. a thin wall), or any other structure fabricated on the top surface of first connection pad 115a. 3D feature 120a may cover a portion of the top surface of first connection pad 115a. At least a portion of the top surface of first connection pad 115a is not covered by 3D feature 120a.

As shown in FIG. 2C, a first electrode layer 231 may be fabricated on substrate 110a, first connection pad 115a, and 3D feature 120a. First electrode layer 231 may include one or more layers of suitable electrically conductive materials (e.g., W, Ru, Mo, Pt, Pd, Ir, TiN, TaN, WN, etc.) deposited on substrate 110a, first connection pad 115a, and 3D feature 120a. At least a portion of first electrode layer 231 directly contacts first connection pad 115a. The first electrode layer 231 also covers 3D feature 120a both the top surface and its sidewalls.

As shown in FIG. 2D, a ferroelectric layer 233 may be fabricated on first electrode layer 231. Ferroelectric layer 233 may include one or more ferroelectric films. Each of the ferroelectric films may include a ferroelectric material. The ferroelectric material may include a metal oxide (e.g., HfO₂, ZrO₂, Hf₁₋ₓZrₓO₂ with x ranging from 0 to 1, Al₁₋ₓScₓN with x>0.3, BaTiO₃, LiNbO₃, NaTaO₃, etc.). In some embodiments, the metal oxide may be doped with one or more substitutional and/or interstitial dopants that may occupy the vacant space between the atoms of the ferroelectric material. The interstitial dopant may include a nonmetal element, such as H, N, C, B, F, etc. Ferroelectric layer 233 may be conformally fabricated on first electrode layer 231. As such, at least a portion of ferroelectric layer 233 may be fabricated atop 3D feature 120a and along its sidewalls. A portion of ferroelectric layer 233 may be fabricated on first connection pad 115a and substrate 110a.

As shown in FIG. 2E, a second electrode layer 235 may be fabricated on ferroelectric layer 233. Second electrode layer 235 may include one or more layers of one or more electrically conductive materials (e.g., W, Ru, Mo, Pt, Pd, Ir, TiN, TaN, WN, etc.). Second electrode layer 235 may be conformally fabricated on ferroelectric layer 233. As such, at least a portion of second electrode layer 235 may be fabricated atop 3D feature 120a and along its sidewalls. A portion of second electrode layer 235 may be fabricated on first connection pad 115a and substrate 110a.

As shown in FIG. 2F, one or more portions of first electrode layer 231, ferroelectric layer 233, and second electrode layer 235 may be selectively removed to fabricate ferroelectric device stack 130a. In particular, first electrode layer 231, ferroelectric layer 233, and second electrode layer 235 may be patterned and etched to fabricate first electrode 131a, ferroelectric layer 133a, and second electrode 135a, respectively.

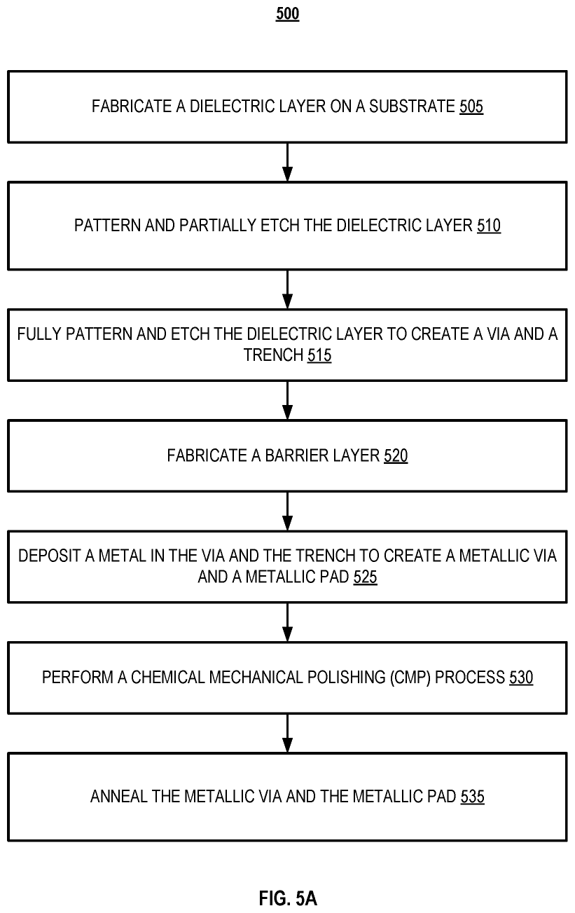

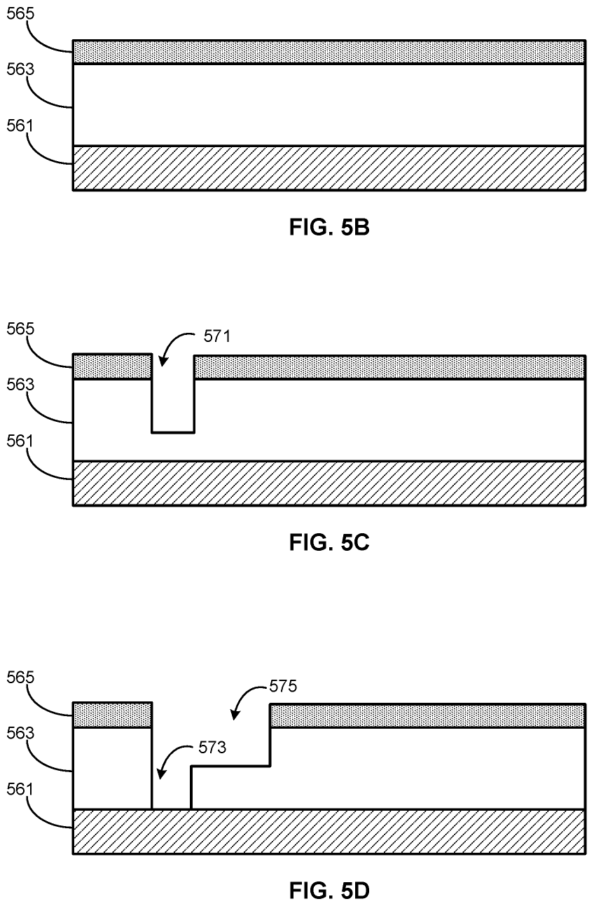

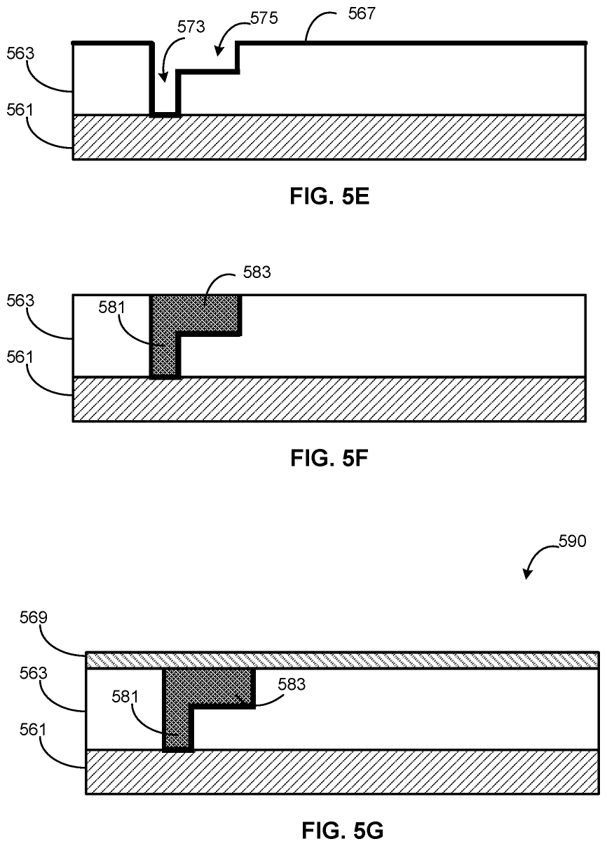

Referring back to FIG. 1A, second connection pad 140a may be fabricated on second electrode 135a. Second connection pad 140a may include a metallic via, a metallic pad, etc. fabricated within dielectric layer 150a. Dielectric layer 150a is fabricated on substrate 110a and envelops the surface of ferroelectric device stack 130a that conformally covers 3D feature 120a and first connection pad 115a. In some embodiments, second connection pad 140a may include an interconnect structure fabricated utilizing a dual-damascene fabrication process (e.g., the process 500 of FIG. 5A).

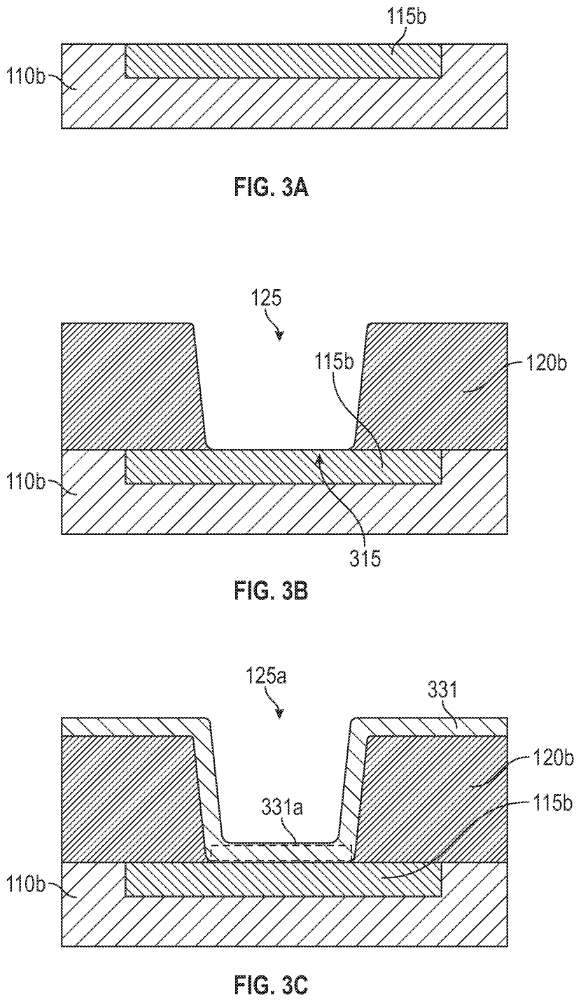

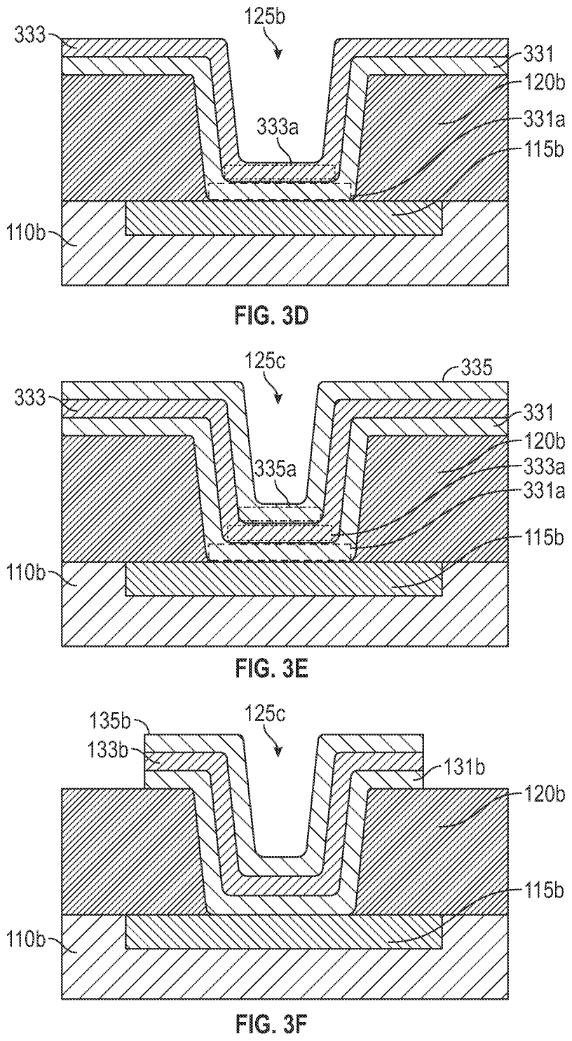

FIGS. 3A, 3B, 3C, 3D, 3E, and 3F illustrate structures related to a process for fabricating a memory device in accordance with some embodiments of the present disclosure.

As shown in FIG. 3A, first connection pad 115b may be fabricated on substrate 110b. First connection pad 115b may include any suitable conductive material, such as metals (e.g., tungsten (W)). In some embodiments, first connection pad 115b may be an interconnect of a CMOS substrate (e.g., a metallic pad, a metallic via, etc.).

As shown in FIG. 3B, a dielectric layer 120b with a 3D feature 125 may be fabricated on first connection pad 115b and substrate 110b. 3D feature 125 may be an opening (e.g., a trench, a via, etc.) and/or any other suitable structure that may expose a portion of the top surface 315 of first connection pad 115b.

As shown in FIG. 3C, a first electrode layer 331 may be conformally fabricated on the entire surface of dielectric layer 120b and 3D feature 125. In particular, first electrode layer 331 may be fabricated on the top surface of dielectric layer 120b, along the sidewalls of 3D feature 125, and on the exposed portion 315 of first connection pad 115b. First electrode layer 331 may fill a portion of 3D feature 125. The unfilled portion of 3D feature 125 is referred to as 3D feature 125a.

As shown in FIG. 3D, a ferroelectric layer 333 may be fabricated on first electrode layer 331. One or more portions of ferroelectric layer 333 (e.g., a portion 333a of ferroelectric layer 333) may be fabricated on the portion 331a of first electrode layer 331. One or more portions of ferroelectric layer 333 may be fabricated in 3D feature 125a. The unfilled portion of 3D feature 125a may be referred to as 3D feature 125b.

As shown in FIG. 3E, a second electrode layer 335 may be fabricated on ferroelectric layer 333. One or more portions of second electrode layer 335 may be fabricated in 3D feature 125b. The unfilled portion of 3D feature 125 may be referred to as 3D feature 125c. In particular, a portion 335a of second electrode layer 335 may be fabricated on the portion 331a of first electrode layer 331.

As shown in FIG. 3F, one or more portions of first electrode layer 331, ferroelectric layer 333, and second electrode layer 335 may be selectively removed to fabricate ferroelectric device stack 130b. In particular, first electrode layer 331, ferroelectric layer 333, and second electrode layer 335 may be patterned and etched to fabricate first electrode 131b, ferroelectric layer 133b, and second electrode 135b, respectively.

Referring back to FIG. 1B, second connection pad 140b may be fabricated on second electrode 135b. A portion of second connection pad 140b may fill 3D feature 125c. Second connection pad 140b may include a metallic via, a metallic pad, etc. Second connection pad 140b may be fabricated in dielectric layer 150b. Dielectric layer 150b is fabricated on dielectric layer 120b and envelops the surface of ferroelectric device stack 130b that conformally covers 3D feature 125 and dielectric layer 120b. In some embodiments, second connection pad 140b may include an interconnection structure fabricated utilizing a dual-damascene fabrication process (e.g., the process 500 of FIG. 5A).

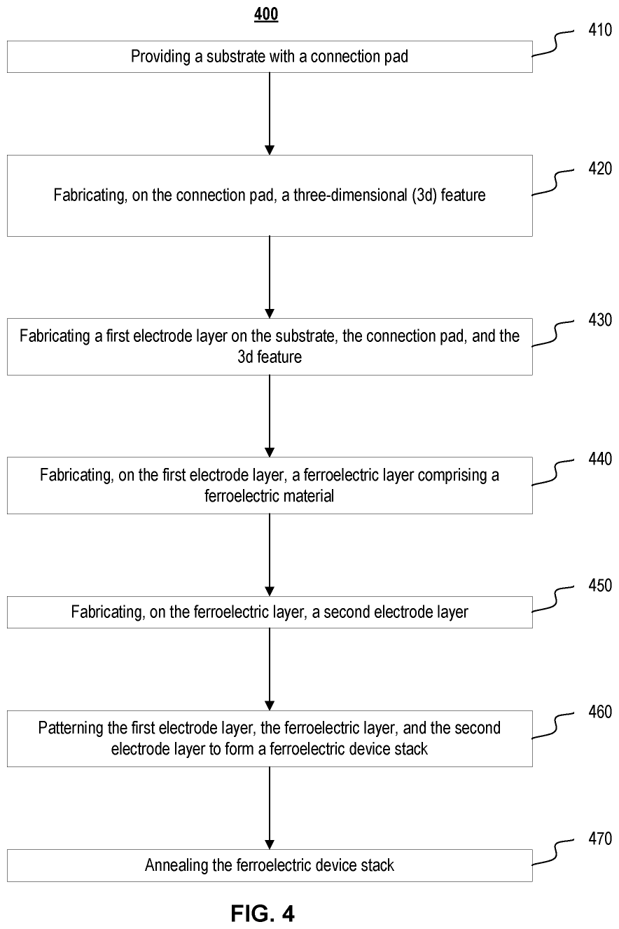

FIG. 4 is a flow chart illustrating an example process 400 for fabricating a memory device in accordance with some embodiments of the present disclosure.

At block 410, a substrate with a first connection pad is provided. The substrate may be the substrate 110a of FIG. 1A and/or substrate 110b of FIG. 1B. The first connection pad may be the first connection pad 115a of FIG. 1A and/or the first connection pad 115b of FIG. 1B.

At block 420, a 3D feature may be fabricated on the first connection pad. In one implementation, the 3D feature may cover one or portions of the first connection pad and may extend out of the two-dimensional plane of the top surface of the substrate, such as a post, a fin, etc. The 3D feature may be, for example, the 3D feature 120a of FIG. 1A. Fabricating the 3D feature may involve depositing a dielectric material (e.g., SiO₂, SiN₄, etc.) on the first connection pad to form a vertical structure (e.g., a post, a fin, etc.). For example, the top surface of the first connection pad and the substrate may be prepared (e.g., by cleaning the top surface of the first connection pad and the substrate). A dielectric material may then be deposited and patterned to fabricate the 3D feature using a deposition process, such as chemical vapor deposition (CVD), physical vapor deposition (PVD), etc. followed by an etching process such as RIE (reactive ion etch), sputter etch, etc. The pattern of the 3D feature (e.g., the dimensions and the geometrics of a post, a fin, etc.) may be defined using photolithography, where a photoresist layer may be applied to the dielectric layer forming the 3D feature 120a. The photoresist is exposed to UV light through a mask, creating the dimensions and geometrics of the 3D feature on the first connection pad. After developing the photoresist to reveal the pattern, an etching process, such as reactive ion etching (RIE) or sputter etch, may be used to remove the exposed dielectric material, creating the 3D feature (e.g., the 3D feature 120a of FIG. 2B) in the dielectric layer.

In another implementation, fabricating the 3D feature may involve fabricating a dielectric layer (e.g., the dielectric layer 120b of FIG. 3B) on the first connection pad and the substrate and fabricating an opening within the dielectric layer. For example, the dielectric layer may be patterned to define the dimensions and geometrics of the 3D feature utilizing photolithography. After developing the photoresist to reveal the pattern, an etching process, such as reactive ion etching (RIE), may be used to remove the exposed dielectric material, creating the 3D feature (e.g., the 3D feature 125 of FIG. 3B) in the dielectric layer (dielectric layer 120b of FIG. 3B).

At block 430, a first electrode layer may be fabricated on the substrate, the first connection pad, and the 3D feature. The first electrode layer may be fabricated by conformally depositing a layer of an electrically conductive material over the entire surface of the substrate, the first connection pad, and the 3D feature. In some embodiments in which the 3D feature includes a post, a fin, etc., the layer of the electrically conductive material may be deposited on the top surface of the substrate, the top surface of the first connection pad, and the top surface of the 3D feature, and along the sidewalls of the 3D feature. In some embodiments in which the 3D feature includes a via, a trench, etc. fabricated in a dielectric layer, the layer of the electrically conductive material may be deposited on the exposed portion of the first electrode layer and the top surface of the dielectric layer, and in the 3D feature.

The electrically conductive material may be deposited utilizing atomic layer deposition (ALD), chemical vapor deposition (CVD), metal-organic chemical vapor deposition (MOCVD), physical vapor deposition (PVD), molecular beam epitaxy (MBE) deposition, etc. The electrically conductive material may include, for example, W, Mo, Ru, TiN, TaN, WN, Pt, Pd, Ir, etc.

At block 440, a ferroelectric layer may be fabricated on the first electrode layer. Fabricating the ferroelectric layer may involve alternately fabricating one or more ferroelectric films using ALD or other suitable deposition techniques. Each of the ferroelectric films may include at least one ferroelectric material (e.g., HfO₂(HfO), ZrO₂(ZO), HZO(Hf_{0.5}Zr_{0.5}O₂), H₁₋ₓZₓO(Hf₁₋ₓZrₓO₂) with x ranging from 0 to 1, etc.). In some embodiments, the ferroelectric layer may include a multilayer structure of multiple ferroelectric films and interface layers alternately stacked on each other. For example, the fabrication of the ferroelectric layer may involve a fabricating process, in which a thin film of a ferroelectric material (e.g., HfO or HZO) is deposited on the first electrode and a thin layer of aluminum oxide (e.g., Al₂O₃) is deposited on top of the ferroelectric film. This fabrication process may be repeated a suitable number of times to create a layered structure of a desirable thickness. In some embodiments, a top ferroelectric layer (e.g., a layer of HfO, a layer of HZO, etc.) may be fabricated on the multilayer structure. In some embodiments, the ferroelectric layer may be fabricated utilizing the techniques described in U.S. patent application Ser. No. 18/539,202, which is incorporated herein by reference in its entirety.

At block 450, a second electrode layer may be fabricated on the ferroelectric layer. For example, a layer of a suitable electrically conductive material (e.g., W, Ru, Mo, Pt, Pd, Ir, TiN, TaN, WN, etc.) may be deposited utilizing suitable deposition techniques, such as ALD, CVD, MOCVD, PVD, MBE, etc.

At block 460, the first electrode layer, the ferroelectric layer, and the second electrode layer may be patterned to form a ferroelectric device stack. The patterning process may involve defining the geometries of the ferroelectric device stack (e.g., ferroelectric device stack 130a of FIG. 1A or ferroelectric device stack 130b of FIG. 1B) and selectively removing one or more portions of the first electrode layer, the ferroelectric layer, and the second electrode layer using suitable etching methods, such as RIE (reactive ion etch), plasma etch, sputter etch, etc.

At block 470, heat treatment, including controlled heating and cooling, may be performed on the memory device and/or the ferroelectric device stack to achieve the desired ferroelectric o-HfO₂ phase. For example, the heat treatment may involve heating and then cooling the first electrode, the ferroelectric layer, and/or the second electrode at controlled rates. More particularly, for example, the memory device may be heated for crystallization of the t-HfO₂ phase and may then be quickly cooled down to form the ferroelectric o-HfO₂ phase. As a more particular example, amorphous HZO may be transformed into the t-phase in a heating process and then transformed to the o-phase in a subsequent cooling process. This process can be accomplished by performing rapid thermal annealing (RTA) at a temperature of 450° C. (ranging from 400° C. to 500° C.) for a duration of 30 seconds (with a possible range of 15 to 60 seconds). Following the heating process, the memory device may be rapidly cooled. Alternatively, block 470 can be performed at the end of fabrication after the devices complete the entire thermal budget.

FIG. 5A is a flow chart illustrating an example process 500 for fabricating an interconnect structure including a metallic via and a metallic pad in one process. FIGS. 5B-5G illustrate cross-sectional views of structures for fabricating an interconnect structure 590 as shown in FIG. 5G by implementing process 500 in accordance with some embodiments of the present disclosure.

As shown, process 500 may start at 505 by fabricating a dielectric layer on a substrate. The substrate may be and/or include one or more transistors, interconnect layers, etc. Depositing the dielectric layer may involve depositing one or more interlayer dielectrics (ILDs), such as SiO₂, Si₃N₄, Al₂O₃, etc. For example, as shown in FIG. 5B, a dielectric layer 563 may be fabricated on a substrate 561. In some embodiments, a resist 565 may be fabricated on the dielectric layer 563.

At 510, the dielectric layer may be patterned and partially etched. That is, the dielectric layer is partially etched in depth. For example, as shown in FIG. 5C, a via 571 may be fabricated by partially etching the dielectric layer 563 and the resist 565.

At 515, the partially etched dielectric layer may be fully etched to create a via and/or a trench. The dielectric is fully etched in depth while maintaining an etching profile for via and trench due to the conformal etching. For example, as shown in FIG. 5D, a via 573 and a trench 575 may be created by etching the partially etched dielectric layer 563 and the resist 565.

At 520, a barrier layer may be fabricated. For example, as shown in FIG. 5E, a barrier layer 567 (e.g., a layer including Ta or TaN) may be deposited on the fully etched dielectric layer and over the sidewalls of the via 573 and the trench 575.

At 525, a metal may be deposited to create a metallic via and a metallic pad. For example, a thin Cu seed layer may be deposited by physical vapor deposition (PVD) followed by the electroplating of Cu, which fills the via and the trench. The metal deposition may also create one or more metal wires. A metal layer may be deposited (e.g., by plating) in the via 573 and the trench 575 to create a metallic via 581 and a metallic pad 583, respectively.

At 530, a chemical mechanical polishing (CMP) process is performed. For example, the metallic via 581, the metallic pad 583, and metal wires (not shown) may be patterned and processed in the CMP process to remove excess Cu and planarize the surface, as shown in FIG. 5F. In some embodiments, as shown in FIG. 5G, a capping layer 569 (e.g., a Ta, TaN, or SiN layer) may be deposited.

At 535, the metallic via and the metallic pad may be annealed. For example, the interconnect structure 590 of FIG. 5G may be annealed at the annealing temperatures (e.g., 350-450° C.) in a forming gas flow (e.g., a mixture of N₂ and H₂) for a suitable period of time (e.g., 15-30 minutes).

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” may be used to mean within ±20% of a target dimension in some embodiments, within ±10% of a target dimension in some embodiments, within ±5% of a target dimension in some embodiments, and yet within ±2% in some embodiments. The terms “approximately” and “about” may include the target dimension.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A memory device, comprising:
a three-dimensional (3D) feature fabricated on a connection pad that comprises a conductive material;
a first electrode, wherein at least a portion of the first electrode is fabricated on a surface of the 3D feature;
a ferroelectric layer fabricated on the first electrode, wherein the ferroelectric layer comprises a ferroelectric material; and
a second electrode fabricated on the ferroelectric layer.

2. The memory device of claim 1, wherein the 3D feature comprises at least one of a post, a fin, a trench, or a via.

3. The memory device of claim 1, wherein the 3D feature comprises an opening fabricated in a dielectric layer, wherein the dielectric layer is fabricated on the connection pad.

4. The memory device of claim 3, wherein the 3D feature exposes at least a portion of the connection pad, and wherein at least a portion of the first electrode is fabricated on the exposed portion of the connection pad.

5. The memory device of claim 4, wherein at least a portion of the first electrode is fabricated on a top surface of the dielectric layer and on sidewalls of the 3D feature.

6. The memory device of claim 1, wherein the connection pad is fabricated on a substrate, and wherein the 3D feature extends out of a two-dimensional plane of a top surface of the substrate.

7. The memory device of claim 6, wherein at least a portion of the first electrode is fabricated on a top surface of the 3D feature and a top surface of the connection pad.

8. The memory device of claim 1, wherein the ferroelectric material comprises a metal oxide, and wherein the metal oxide comprises at least one of hafnium oxide (HfO₂), zirconium oxide (ZrO₂), zirconium-doped hafnium oxide (Hf₁₋ₓZrₓO₂ with x ranging from 0 to 1), scandium-doped aluminum nitride (Al₁₋ₓScₓN with x>0.3), titanates (BaTiO₃), niobates (LiNbO₃), or tantalates (NaTaO₃).

9. The memory device of claim 1, wherein the ferroelectric material is interstitially doped with at least one interstitial dopant, and wherein the at least one interstitial dopant comprises at least one of H, N, C, B, or F.

10. The memory device of claim 1, wherein the first electrode comprises at least one of tungsten, ruthenium, molybdenum, titanium nitride, tantalum nitride, tungsten nitride, platinum, palladium, or iridium.

11. The memory device of claim 1, wherein the second electrode comprises at least one of tungsten, ruthenium, molybdenum, titanium nitride, tantalum nitride, tungsten nitride, platinum, palladium, or iridium.

12. A method for fabricating a memory device, the method comprising:
fabricating, on a connection pad comprising a conductive material, a three-dimensional (3D) feature, wherein the connection pad is fabricated on a substrate;
fabricating a first electrode layer on the substrate, the connection pad, and the 3D feature;
fabricating, on the first electrode layer, a ferroelectric layer comprising a ferroelectric material; and
fabricating, on the ferroelectric layer, a second electrode layer.

13. The method of claim 12, wherein the 3D feature comprises at least one of a post, a fin, a trench, or a via.

14. The method of claim 12, wherein fabricating, on the connection pad, the 3D feature comprises fabricating a dielectric layer with an opening on the connection pad.

15. The method of claim 14, wherein the 3D feature exposes at least a portion of the connection pad, and wherein at least a portion of the first electrode is fabricated on the exposed portion of the connection pad.

16. The method of claim 15, wherein at least a portion of the first electrode is fabricated on a top surface of the dielectric layer and sidewall of the opening of the dielectric layer.

17. The method of claim 12, wherein the connection pad is fabricated on a substrate, and wherein the 3D feature extends out of a two-dimensional plane of a top surface of the substrate.

18. The method of claim 17, wherein at least a portion of the first electrode is fabricated on a top surface of the 3D feature and a top surface of the connection pad.

19. The method of claim 12, wherein the ferroelectric material comprises a metal oxide, and wherein the metal oxide comprises at least one of hafnium oxide (HfO₂), zirconium oxide (ZrO₂), zirconium-doped hafnium oxide (Hf₁₋ₓZrₓO₂ with x ranging from 0 to 1), scandium-doped aluminum nitride (Al₁₋ₓScₓN with x>0.3), titanates (BaTiO₃), niobates (LiNbO₃), or tantalates (NaTaO₃).

20. The method of claim 12, wherein the first electrode comprises at least one of tungsten, ruthenium, molybdenum, titanium nitride, tantalum nitride, tungsten nitride, platinum, palladium, or iridium, and wherein the second electrode comprises at least one of tungsten, ruthenium, molybdenum, titanium nitride, tantalum nitride, tungsten nitride, platinum, palladium, or iridium.
